(19) United States
(12) Patent Application Publication
(10) Pub. No.: US 2025/0313092 A1
(43) Pub. Date: Oct. 9, 2025

(54) STATE OF CHARGE MASKING

(71) Applicant: Volve Truck Corporation, GÖTEBORG (SE)

(72) Inventors: Marcus VIKÉN, GÖTEBORG (SE); Lucas BILLSTEIN, HISINGS BACKA (SE); Adam BORGELSSON MAANINKA, TORSLANDA (SE)

(21) Appl. No.: 19/078,570

(22) Filed: Mar. 13, 2025

(30) Foreign Application Priority Data
Apr. 5, 2024 (EP) 24168819.1

(51) Int. Cl. B60L 3/00; B60L 58/12

(52) U.S. Cl. CPC B60L 3/0046; B60L 58/12

(57) ABSTRACT

A computer system is presented. The computer system comprises processing circuitry configured to obtain measured state of charge, SOC, data of an energy source of a vehicle and determine that a measured SOC decrease rate is above an expected SOC decrease rate by a predetermined SOC decrease rate threshold. The processing circuitry is further configured to determine an SOC difference based on the measured SOC data and the expected SOC decrease rate, and determine an SOC correction based on the SOC difference. The processing circuitry is further configured to reduce an SOC buffer of the energy source by the SOC correction, and provide filtered SOC data of the energy source by increasing the measured SOC data by the SOC correction.

### PRIORITY APPLICATIONS

The present application claims priority to European Patent Application No. 24168819.1, filed on Apr. 5, 2024, and entitled “STATE OF CHARGE MASKING,” which is incorporated herein by reference in its entirety.

### TECHNICAL FIELD

The disclosure relates generally to management of energy in an electric vehicle. In particular aspects, the disclosure relates to masking of a state of charge of energy sources of an electrified vehicle. The disclosure can be applied to heavy-duty vehicles, such as trucks, buses, and construction equipment, among other vehicle types. Although the disclosure may be described with respect to a particular vehicle, the disclosure is not restricted to any particular vehicle.

### BACKGROUND

Accurately estimating a state of charge (SOC) of energy sources, such as batteries, in an electric vehicle (EV) is important. Failure to reliably estimate a current SOC of a battery may cause the battery to deplete during operation or cause the battery to be charged even though it is not needed. Deep discharges may, depending on battery technology, degrade a capacity of the battery and potentially reduce a lifetime of the battery.

However, accurate estimation of SOC of a battery is challenging; a relationship between a battery voltage, a current, and an SOC is generally nonlinear and may be affected by various factors such as temperature, aging, and load conditions of the battery.

### SUMMARY

According to a first aspect of the disclosure, a computer system is presented. The computer system comprises processing circuitry configured to: obtain measured state of charge, SOC, data of an energy source of a vehicle, determine that a measured SOC decrease rate is above an expected SOC decrease rate by a predetermined SOC decrease rate threshold; determine an SOC difference based on the measured SOC data and the expected SOC decrease rate; determine an SOC correction based on the SOC difference; reduce an SOC buffer of the energy source by the SOC correction; and provide filtered SOC data of the energy source by increasing the measured SOC data by the SOC correction. The first aspect of the disclosure may seek to reduce a risk that a higher SOC than actually available is provided. Technical benefits may include reduced anxiety of an operator of the vehicle, reduction of sudden shifts in reported SOC, and/or reduced risk of the vehicle running out of energy during operation

Optionally in some examples, including in at least one preferred example, the processing circuitry is further configured to: determine the expected SOC decrease rate based on energy drained from the energy source. A technical benefit may include accurate detections of e.g. calibration events and similar occurring at the energy source.

Optionally in some examples, including in at least one preferred example, the processing circuitry is further configured to: the processing circuitry is further configured to: determine that the measured SOC data is below a predetermined maximum SOC threshold and above an intermediate SOC threshold; increase the SOC buffer by an SOC increase value; and provide filtered SOC data of the energy source by decreasing the measured SOC data by the SOC increase value. A technical benefit may include controllably and smoothly and without adversely affecting propulsion of the vehicle, providing a buffer for the SOC.

Optionally in some examples, including in at least one preferred example, the processing circuitry is further configured to: determine that the measured SOC data is below the intermediate SOC threshold and above a minimum SOC threshold; decrease the SOC buffer by an SOC decrease value; and provide filtered SOC data of the energy source by increasing the measured SOC data by the SOC decrease value. A technical benefit may include controllably and smoothly and without adversely affecting propulsion of the vehicle, reducing a buffer for the SOC.

Optionally in some examples, including in at least one preferred example, the processing circuitry is further configured to: determine the SOC decrease value such that the SOC buffer is substantially zero when the measured SOC data is at the minimum SOC threshold. A technical benefit may include providing the SOC buffer without affecting a range of the vehicle.

Optionally in some examples, including in at least one preferred example, the processing circuitry is further configured to: determine that the SOC difference is greater than the SOC buffer; reduce a minimum SOC threshold by the by the SOC correction; and prevent propulsion of the vehicle responsive to the measured SOC data being below the minimum SOC threshold. A technical benefit may include masking shifts in the measured SOC even when the SOC buffer is substantially empty.

Optionally in some examples, including in at least one preferred example, the SOC buffer is equal to a minimum SOC threshold, and the processing circuitry is further configured to: prevent propulsion of the vehicle responsive to the measured SOC data being below the minimum SOC threshold. A technical benefit may include controllably and smoothly and without adversely affecting propulsion of the vehicle, reducing a buffer for the SOC.

Optionally in some examples, including in at least one preferred example, the processing circuitry is further configured to: determine that an SOC decrease rate is above the expected SOC decrease rate by comparing measured SOC data to previous measured SOC data. A technical benefit may include accurate detections of e.g. calibration events and similar occurring at the energy source.

Optionally in some examples, including in at least one preferred example, the processing circuitry is further configured to: determine the expected SOC decrease rate based on energy drained from the energy source; determine that the measured SOC data is below a predetermined maximum SOC threshold and above an intermediate SOC threshold, increase the SOC buffer by an SOC increase value, and provide filtered SOC data of the energy source by decreasing the measured SOC data by the SOC increase value; determine that the measured SOC data is below the intermediate SOC threshold and above a minimum SOC threshold, decrease the SOC buffer by an SOC decrease value, and provide filtered SOC data of the energy source by increasing the measured SOC data by the SOC decrease value; determine the SOC decrease value such that the SOC buffer is substantially zero when the measured SOC data is at the minimum SOC threshold; determine that the SOC difference is greater than the SOC buffer, reduce a minimum SOC threshold by the by the SOC correction, and prevent propulsion of the vehicle responsive to the measured SOC data being below the minimum SOC threshold; determine that an SOC decrease rate is above the expected SOC decrease rate by comparing measured SOC data to previous measured SOC data; and determine that an SOC decrease rate is above the expected SOC decrease rate by obtaining an SOC data calibration event indicator from the energy source. A technical benefit may include, in addition to the benefits listed above, that even more accurate detections of e.g. calibration events and similar occurring at the energy source is provided.

According to a second aspect of the disclosure, a battery pack is presented. The battery pack comprises one or more battery cells and the computer system of the first aspect configured to obtain measured SOC data of at least one of the one or more battery cells. The second aspect of the disclosure may seek to reduce a risk that a higher SOC than actually available is provided. Technical benefits may include reduced anxiety of an operator of the vehicle, reduction of sudden shifts in reported SOC and reduced risk of the vehicle running out of energy during operation

According to a third aspect of the disclosure, an energy management system is presented. The energy management system comprises one or more battery packs and the computer system of the first aspect configured to obtain measured SOC data of at least one of the one or more battery packs. The third aspect of the disclosure may seek to reduce a risk that a higher SOC than actually available is provided. Technical benefits may include reduced anxiety of an operator of the vehicle, reduction of sudden shifts in reported SOC and reduced risk of the vehicle running out of energy during operation.

According to a fourth aspect of the disclosure, a vehicle is presented. The vehicle comprises one or more energy sources and the computer system of any one of claims 1 to 9 configured to obtain measured SOC data of at least one of the one or more energy sources. The fourth aspect of the disclosure may seek to reduce a risk that a higher SOC than actually available is provided. Technical benefits may include reduced anxiety of an operator of the vehicle, reduction of sudden shifts in reported SOC and reduced risk of the vehicle running out of energy during operation.

According to a fifth aspect of the disclosure, a computer implemented method is presented. The computer implemented method comprises obtaining, by processing circuitry of a computer system, measured state of charge, SOC, data of an energy source of a vehicle, determining, by processing circuitry of the computer system, that a measured SOC decrease rate is above an expected SOC decrease rate by a predetermined SOC decrease rate threshold; determining, by processing circuitry of the computer system, an SOC difference based on the measured SOC data and the expected SOC decrease rate; determining, by processing circuitry of the computer system, an SOC correction based on the SOC difference; reducing, by processing circuitry of the computer system, an SOC buffer of the energy source by the SOC correction; and providing, by processing circuitry of the computer system, filtered SOC data of the energy source by increasing the measured SOC data by the SOC correction. The fifth aspect of the disclosure may seek to reduce a risk that a higher SOC than actually available is provided. Technical benefits may include reduced anxiety of an operator of the vehicle, reduction of sudden shifts in reported SOC and reduced risk of the vehicle running out of energy during operation.

According to a sixth aspect of the disclosure, a computer program product is presented. The computer program product comprises program code for performing, when executed by processing circuitry, the computer implemented method of the fifth aspect. The sixth aspect of the disclosure may seek to reduce a risk that a higher SOC than actually available is provided. Technical benefits may include reduced anxiety of an operator of the vehicle, reduction of sudden shifts in reported SOC and reduced risk of the vehicle running out of energy during operation.

According to a seventh aspect of the disclosure, a non-transitory computer-readable storage medium is presented. The non-transitory computer-readable storage medium comprises instructions, which when executed by processing circuitry, cause the processing circuitry to perform the computer implemented method of the fifth aspect. The seventh aspect of the disclosure may seek to reduce a risk that a higher SOC than actually available is provided. Technical benefits may include reduced anxiety of an operator of the vehicle, reduction of sudden shifts in reported SOC and reduced risk of the vehicle running out of energy during operation.

The disclosed aspects, examples (including any preferred examples), and/or accompanying claims may be suitably combined with each other as would be apparent to anyone of ordinary skill in the art. Additional features and advantages are disclosed in the following description, claims, and drawings, and in part will be readily apparent therefrom to those skilled in the art or recognized by practicing the disclosure as described herein.

There are also disclosed herein computer systems, control units, code modules, computer-implemented methods, computer readable media, and computer program products associated with the above discussed technical benefits.

### BRIEF DESCRIPTION OF THE DRAWINGS

Examples are described in more detail below with reference to the appended drawings.

FIG. 1 is a side view of an exemplary vehicle according to an example.

FIG. 2 is a schematic view of an exemplary SOC masker according to an example.

FIG. 3 are exemplary time-series plots of SOCs and SOC buffer according to an example.

FIG. 4 are exemplary time-series plots of SOCs and SOC buffer according to an example.

FIG. 5 are exemplary time-series plots of SOCs and SOC buffer according to an example.

FIG. 6A is an exemplary block diagram of a computer system according to an example.

FIG. 6B is an exemplary block diagram of an energy source according to an example.

FIG. 6C is an exemplary block diagram of a battery pack according to an example.

FIG. 6D is an exemplary block diagram of an energy management system according to an example.

FIG. 7 is a schematic view of a method according to an example.

FIG. 8 is a block diagram of a computer program product according to an example.

FIG. 9 is a schematic view of an exemplary SOC masker according to an example.

FIG. 10 is a schematic diagram of an exemplary computer system for implementing examples disclosed herein, according to an example.

### DETAILED DESCRIPTION

The detailed description set forth below provides information and examples of the disclosed technology with sufficient detail to enable those skilled in the art to practice the disclosure.

An operator of an electric vehicle (EV) will generally consult a state of charge (SOC) indicator at an instrument cluster of the EV to learn how much energy is left in an energy source of the EV. Based on the indicated SOC, the operator may try to estimate a remaining distance the EV may travel before the energy source needs to be charged. As indicated above, estimating the SOC is challenging. Further, inaccuracies in the estimated SOC may accumulate over time when charging/discharging the energy source of the EV.

Generally, processes are in place that detect inaccuracies in the estimation of SOC and attempt to correct these inaccuracies once detected. Generally, such corrections will cause the SOC to drop/jump comparably fast, sometimes several percentage points (units of percent). If a correction downwards, i.e. it is determined that the estimated SOC is too high, would happen at a low SOC region, this may cause significant anxiety to the driver. If a correction upwards, i.e. it is determined that the estimated SOC is too low, would happen at a low SOC region, the driver may become overconfident in estimating a remaining route at specific SOC levels. Sudden shifts in the reported SOC may cause operators of EVs to lose faith in the estimated SOC and lead to unnecessary charging time (decreased utilization) increasing cost of ownership of the EV. The latter is of particular importance if the EV is a commercial vehicle such as, but not limited to, trucks or other transportation vehicles.

The present disclosure provides a computer system and a method that will mask sudden SOC drops increasing a user experience for the operator. The teachings herein will obscure an SOC reported from an energy source and present an SOC that is slightly lower than the SOC reported from the energy source. The difference between the SOC reported from the energy source and the presented SOC is referred to as an SOC buffer. If a sudden drop in SOC is determined, the unit of percent in SOC that was lost in the drop may be deducted from the SOC buffer and no sudden shift is required in the presented SOC.

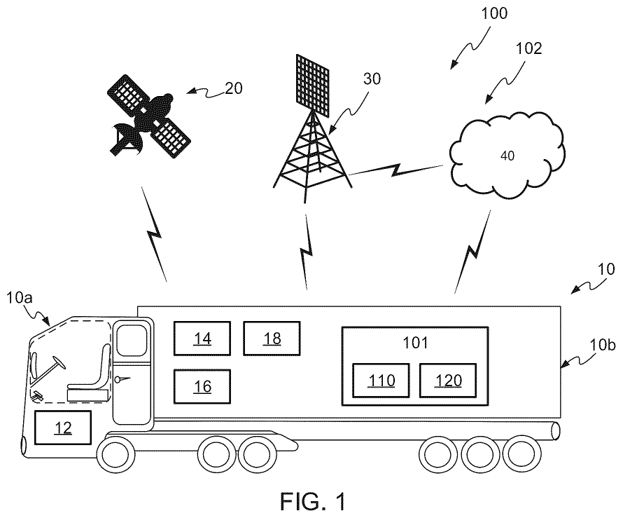

FIG. 1 is an exemplary schematic side view of a heavy-duty vehicle 10 (hereinafter referred to as vehicle 10). The vehicle 10 comprises a tractor unit 10a which is arranged to tow a trailer unit 10b. In other examples, other vehicles may be employed, e.g., trucks, buses, and construction equipment. The vehicle 10 comprises all vehicle units and associated functionality to operate as expected, such as a powertrain, chassis, and various control systems. The vehicle 10 comprises one or more propulsion sources 12. The propulsion source 12 may be any suitable propulsion source 12 exemplified by, but not limited to one or more electrical motors or, one or more electrical motors in combination with one or more combustion engines such as a diesel, gas or gasoline powered engines. The vehicle 10 further comprises an energy source 14 suitable for providing energy for the propulsion source 12. That is to say, if the propulsion source 12 is an electrical motor, a suitable energy source 14 would be a battery or a fuel cell. The vehicle 10 further comprises sensor circuitry 16 arranged to detect, measure, sense or otherwise obtain data relevant for operation of the vehicle 10. The sensor circuit 16 may comprise one or more of a current sensor, a voltage sensor, a coulomb counter, an accelerometer, a gyroscope, a wheel speed sensor, an ABS sensor, a throttle position sensor, a fuel level sensor, a temperature sensor, a pressure sensor, a rain sensor, a light sensor, proximity sensor, a lane departure warning sensor, a blind spot detection sensor, a TPMS sensor etc. Operational data relevant for operation of the vehicle 10 may include, but is not limited to, one or more of a speed of the vehicle 10, a weight of the vehicle 10, an inclination of the vehicle 10, a status of the energy source 14 of the vehicle 10 (SOC, fuel level etc.), a current speed limit of a current road travelled by the vehicle 10, etc. The vehicle 10 may further comprise communications circuitry 18 configured to receive and/or send communication. The communications circuitry 18 may be configured to enable the vehicle 10 to communicate with one or more external devices or systems such as a cloud server 40. The communication with the external devices or systems may be directly or via a communications interface such as a cellular communications interface 30, such as a radio base station. The cloud server 40 may be any suitable cloud server exemplified by, but not limited to, Amazon Web

Services (AWS), Microsoft Azure, Google Cloud Platform (GCP), IBM Cloud, Oracle Cloud Infrastructure (OCI), DigitalOcean, Vultr, Linode, Alibaba Cloud, Rackspace etc. The communications interface may be a wireless communications interface exemplified by, but not limited to, Wi-Fi, Bluetooth, Zigbee, Z-Wave, LoRa, Sigfox, 2G (GSM, CDMA), 3G (UMTS, CDMA2000), 4G (LTE), 5G (NR) etc. The communication circuitry 18 may, additionally or alternatively, be configured to enable the vehicle 10 to be operatively connected to a Global Navigation Satellite System (GNSS) 20 exemplified by, but not limited to, global positioning system (GPS), Globalnaya Navigatsionnaya Sputnikovaya Sistema (GLONASS), Galileo, BeiDou Navigation Satellite System, Navigation with Indian Constellation (NavIC) etc. The vehicle 10 may be configured to utilize data obtain from the GNSS 20 to determine a geographical location of the vehicle 10.

The vehicle 10 thus forms part of, or implements, a computer system 100 comprising processing circuitry 102 configured to mask sudden SOC drops as will be described in the following. To achieve this, the vehicle 10 comprises a computing device 101. The computing device 101 may be operatively connected to the communications circuitry 18, the sensor circuitry 16, the energy source 14, and/or the propulsion source 12 of the vehicle 10. The computing device 101 comprises a processor 110. The computing device 101 may comprise a storage device 120, advantageously a non-volatile storage device such as a hard disk drives (HDDs), solid-state drives (SSDs) etc. In some examples, the storage device 120 is not comprised in the computing device 101 but rather operatively connected to the computing device 101.

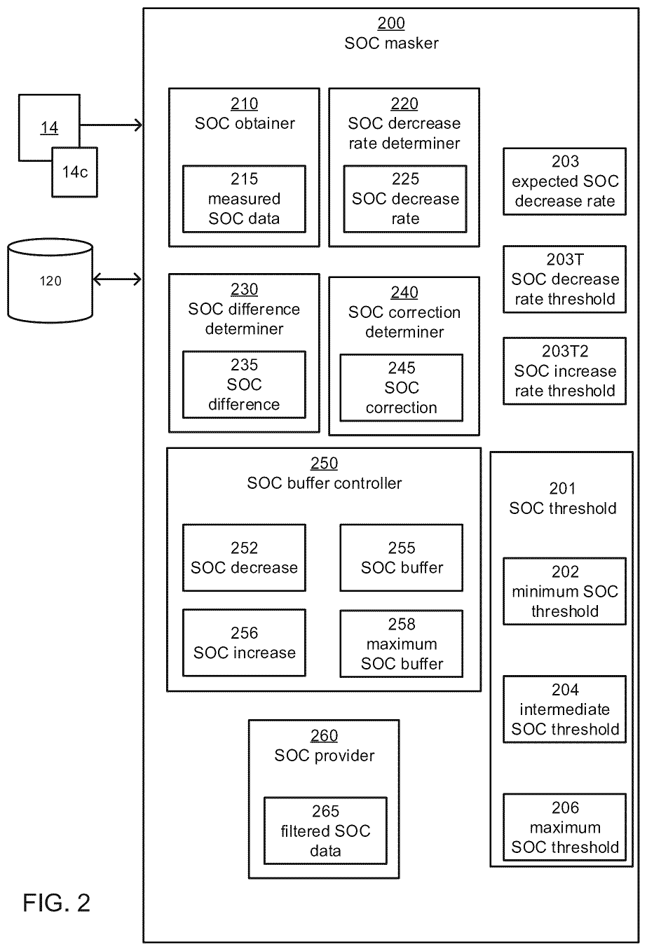

With reference to FIG. 2, an architectural overview of an exemplary SOC masker 200 will be presented. The computer system 100, or rather the processor 110 of the computing device 101, may configured to perform, or cause performance of, any or all features of the SOC masker 200. The SOC masker 200 comprises an SOC obtainer 210, an SOC decrease rate determiner 220, an SOC difference determiner 230, an SOC correction determiner 240, an SOC buffer controller 250, and an SOC provider 260, these will be described in further detail in the following. The SOC masker 200 is generally associated with a specific energy source 14, which may be a battery pack, a group of battery packs, a battery cell, etc. In some examples, the energy source 14 is an energy source of a vehicle 10. The SOC masker 200 provides filtered SOC data 265 that reduces a risk of an operator of a vehicle 10 being exposed to excessive and/or sudden jumps or shift in an SOC indication of the vehicle 10.

The SOC obtainer 210 is configured to obtain, measure or otherwise acquire measured SOC data 215 of an energy source 14 of a vehicle 10. The actual measurement of the measured SOC data 215 may be provided by circuitry of the energy source 14, the vehicle 10 and/or the SOC obtainer 210. The measured SOC data 215 describes at least an SOC of the energy source 14 but may provide data describing other parameters of the energy source 14 such as, but not limited to, a voltage of the energy source 14, a current from (discharge current) or to (charge current) the energy source 14, a temperature of the energy source 14, a state of health SoH of the energy source, etc.

The SOC of the energy source 14 may be measured in any suitable way for instance by voltage measurement of the energy source 14. The voltage of an energy source 14 generally relate to an SOC of the energy source 14. However, the relationship between voltage and SOC generally requires measurement of an open cell voltage (OCV) and even then, the relationship may not be linear and may vary depending on factors like temperature and battery chemistry.

Impedance spectroscopy is an alternative method of estimating the SOC of an energy source 14. By analyzing an impedance of the energy source 14 at different frequencies, an SOC of the energy source 14 may be inferred. Impedance spectroscopy involves applying a comparably small AC signal to the energy source 14 and measuring the response. A changes in impedance may indicate changes in SOC. Impedance spectroscopy is generally considered complex and requires specialized hardware to provide the AC signal and obtain the response.

Another way of estimating the SOC of the energy source 14 is by coulomb counting. Coulomb counting involves integrating a current flowing into or out of the energy source 14 over time. By tracking a total charge transferred, the SOC may be estimated.

Generally, estimations of SOC are associated with some uncertainty and may be subject to drift due to temperature changes, inaccuracies in current measurements, control loop wind-up, noise, etc. Due to this, two or more SOC estimation techniques are generally paired when estimating SOC to compensate for SOC drift. Techniques like Kalman filters or extended Kalman filters may be used to continuously estimate the SOC while simultaneously detecting drift. If a drift is detected, or for other purposes, the SOC estimation may be calibrated to correct drifts over time. This generally involves comparing the estimated SOC with a reference SOC obtained through more accurate means, such as full charge-discharge cycles, and adjusting the estimation algorithm accordingly. The calibration of the estimated SOC may result in a shift of the measured SOC 215. These shifts in the measured SOC 215 may, as previously explained, cause anxiety of an operator of the vehicle 10.

To this end, the SOC decrease rate determiner 220 is configured to determine an SOC decrease rate 225. The SOC decrease rate 225 may be determined by comparing current measured SOC data 215 to previously measured SOC data 215, specifically comparing a current SOC of the energy source 14 to a previous SOC of the energy source 14. The SOC decrease rate 225 may be determined for a predetermined or configurable time period. The time period may not be a time per say, but may be defined as number of sample periods for the measured SOC data 215. In some examples, the measured SOC data 215 may be compared to a sliding average of a number of previously measured SOC data 215. Also, the measured SOC data 215 may be formed by averaging over a number of samples of measured SOC data 215. Averaging the measured SOC data 215 reduces noise in the measured data.

The SOC decrease rate determiner 220 may be configured to compare the SOC decrease rate 225 to an expected SOC decrease rate 203 of the SOC masker 200. The expected SOC decrease rate 203 describes an expected decrease rate of the SOC of the energy source 14. The expected decrease rate 203 may be a predetermined rate fixed rate independent of loading conditions (input current, output current etc.) and/or operating conditions (temperature, humidity etc.) for the energy source 14. In some examples, the expected decrease rate 203 is a variable decrease rate that may vary depending on current loading conditions and/or current operating conditions. In some examples, the SOC masker 200 is configured to determine the expected decrease rate 203 based on a current energy drained from the energy source 14. In some examples, the energy drained from the energy source 14 is obtained by (based on) coulomb counting of a current drained from the energy source 14.

In some examples, the SOC decrease rate determiner 220 may be configured to obtain an SOC data calibration event indicator 14c form the energy source 14. The SOC data calibration event indicator 14c may be configured to indicate that a calibration of the energy source 14 has occurred, or is about to occur. The SOC decrease rate determiner 220 may be configured to selectively determine the SOC decrease rate 225 responsive to obtaining the SOC data calibration event indicator 14c. In some examples, the SOC data calibration event indicator 14c may comprise the SOC decrease rate 225, and/or any other data indicating an amount of change in SOC of the energy source 14 the recalibration caused. The SOC decrease rate determiner 220 may be configured to determine the SOC decrease rate 225 based on the SOC data calibration event indicator 14c.

The SOC decrease rate determiner 220 may be configured to compare the SOC decrease rate 225 to the expected SOC decrease rate 203 to determine if the SOC decrease rate 225 is above the expected SOC decrease rate 203. In some examples, the SOC decrease rate determiner 220 may be configured to compare the SOC decrease rate 225 to the expected SOC decrease rate 203 to determine if the SOC decrease rate 225 is above the expected SOC decrease rate 203 by a predetermined SOC decrease rate threshold 203T. The SOC decrease rate threshold 203T reduces a risk that temporary noise, incorrect measurements or other factors cause the SOC decrease rate determiner 220 to incorrectly determine that the SOC decrease rate 225 is above the expected SOC decrease rate 203.

Responsive to the SOC decrease rate determiner 220 determining that the SOC decrease rate 225 is above the expected SOC decrease rate 203 (strictly above or by the SOC decrease rate threshold 203T), the SOC difference determiner 230 may be configured to determine an SOC difference 235. The SOC difference determiner 230 may be configured to determine the SOC difference 235 based on the measured SOC data 215 and the expected SOC decrease rate 203. In some examples, the SOC difference determiner 230, may be configured to determine the SOC difference 235 by decreasing a previous SOC measurement based on the expected SOC rate 203 and compare the decreased previous SOC measurement to the measured SOC data 215.

In other words, the SOC decrease rate determiner 220 may be described as determining if the SOC of the energy source 14 has decreased more than expected. The SOC difference 235 may be described as how much more than expected, the SOC of the energy source 14 has decreased. That is to say, based on the SOC decrease rate determiner 220 and the SOC difference determined 230, the SOC masker 200 may determine that, and how much, the measured SOC data 215 differs from expected SOC data.

Responsive to the SOC decrease rate determiner 220 determining that the SOC decrease rate 225 is above the expected SOC decrease rate 203 (strictly above or by the SOC decrease rate threshold 203T), the SOC correction determiner 240 may be configured to determine an SOC correction 245. The SOC correction 245 describes how much the measured SOC data 215 is to be increased prior to reporting the filtered SOC data 265. The SOC correction determiner 240 may be configured to determine the SOC correction 245 based on the SOC difference 235. In some examples, the SOC correction 245 is equal to the SOC difference 235. In some examples, the SOC correction 245 is the SOC difference 235 multiplied by a scaling factor. The scaling factor is, in some examples, lower than 1 but greater than 0. In other words, the scaling factor may be provided such that not the entire SOC difference 235 is corrected by the SOC correction 245. This will present a slight shift also in the filtered SOC data 265, but, as will be seen in the following, a maximum SOC buffer 258 may be decreased.

Consequently, if the filtered SOC data 265 is the measured SOC data 215 increased by the SOC difference 235, or the SOC difference multiplied by the scaling factor, the filtered SOC data 265, i.e. the SOC data provided for presentation to an operator of the vehicle 10 of for processing by other devices, services of circuitry of the vehicle 10, exhibits a smaller, or no, jump in SOC compared to a previous SOC of the energy source 14. Among other things, this reduces a risk that an operator gets agitated by sudden shift in the reported SOC of the energy source 14, or even is forced to stop driving due to the SOC being below a minimum SOC threshold 202.

In order to not simply obscure the true SOC of the energy source and provide a false sense of security for the operator of the vehicle 10, an SOC buffer 255 is provided. The SOC buffer 255 is controlled by the SOC buffer controller 250. The SOC buffer 255 may be described as a temporary and virtual SOC storage that allows shifts in the measured SOC data 215 to be masked. Consequently, if the filtered SOC data 265 is increased by the SOC correction 245, the SOC buffer controller 250 will decrease the SOC buffer 255 by the SOC correction 245. In other words, an increase of the filtered SOC data 265 compared to the measured SOC data 215 will lead to a corresponding decrease of the SOC buffer 255.

The SOC buffer controller 250 may, in some examples, further be configured to increase and/or decrease the SOC buffer 255 independently of the SOC decrease rate determiner 220 determining that the SOC decrease rate 225 is above the expected SOC decrease rate 203 (strictly above or by the SOC decrease rate threshold 203T). In some examples, the SOC buffer controller 250 may be configured to increase the SOC buffer 255 selectively under certain conditions, and to decrease the SOC buffer 255 selectively under other conditions. Since the SOC buffer 255 is a virtual buffer and not a true energy storage, SOC buffer controller 250 may be configured to control the SOC buffer 255 to approach zero (i.e. empty) when the measured SOC data 215 is close to the minimum SOC threshold 202, i.e. a minimum usable SOC of the vehicle 10. A sudden shift in SOC will cause less anxiety if the energy source 14 is close to full, to this end, in some examples, the SOC buffer controller 250 may be configured to increase the SOC buffer 255 when the measured SOC data 215 is comparably high. In some examples during charging, the SOC buffer 255 is reset, i.e. set to zero, when the energy source 14 is substantially fully charged.

Generally, the SOC provider 260 is configured to provide the filtered SOC data 265 as a previous filtered SOC data decreased by the measured SOC decrease rate 225. Responsive to the SOC decrease rate determiner 220 determining that the SOC decrease rate 225 is above the expected SOC decrease rate 203 (strictly above or by the SOC decrease rate threshold 203T), i.e. that an SOC masking is to take place, the filtered SOC data 265 is provided as the precious filtered SOC data decreased by the measured SOC decrease rate 225 and increased by the SOC correction 245. Generally, whenever the SOC buffer controller 250 increases the SOC buffer 255, the SOC provider 260 is configured to decrease the filtered SOC data 265 correspondingly. Analogously, whenever the SOC buffer controller 250 decreases the SOC buffer 255, the SOC provider 260 is configured to increase the filtered SOC data 265 correspondingly.

In some examples, the SOC buffer controller 250 may be configured to compare the measured SOC data 215 to one or more SOC thresholds 201. For example, the one or more SOC thresholds 201 comprises a predetermined maximum SOC threshold 206, an intermediate SOC threshold 204 and/or the minimum SOC threshold 202.

The predetermined maximum SOC threshold 206 may be chosen freely, and may be chosen to indicate at what SOC the energy source 14 is considered to be full, i.e. the SOC is 100%. The maximum SOC threshold 206 does not necessarily correspond to a physical maximum energy level of the energy source 14, but may be a level slightly below the physical maximum energy level. This generally increases a lifetime of the energy source and allows for an increased number of charging/discharging cycles. In some examples, the maximum SOC threshold 206 may be configured to be at a level that is below an SOC at which the energy source 14 is considered to be full (which in turn may be below the physical maximum energy level of the energy source 14).

The minimum SOC threshold 202 may be a threshold indicating at what SOC the energy source 14 is considered to be empty, i.e. the SOC is 0%. The minimum SOC threshold 202 does not necessarily correspond to a physical minimum energy level of the energy source 14, but may be a level slightly above the physical minimum energy level. Correspondingly to the maximum SOC threshold 206, this generally increases a lifetime of the energy source and allows for an increased number of charging/discharging cycles. As will be explained, the minimum SOC threshold 202 may be a configurable threshold.

The intermediate SOC threshold 204 is a threshold indicating an SOC value of the energy source between the minimum SOC threshold 202 and the maximum SOC threshold 206. In some examples, the intermediate SOC threshold 204 is somewhere between 25% and 75% of a total SOC of the energy source 14. In some examples, the intermediate SOC threshold 204 is at 35% of the total SOC of the energy source 14. In some examples, the intermediate SOC threshold 204 is at 65% of the total SOC of the energy source 14. In some examples, the intermediate SOC threshold 204 is at 50% of the total SOC of the energy source 14. As the risk of recalibration events and jumps in the measured SOC data 215 may increase as the measured SOC data 215 closes in on the minimum SOC threshold 202, in some examples, the intermediate SOC threshold 204 is at 10 percent points above the minimum SOC threshold 202. In some examples the intermediate SOC threshold 204 is at 5 percent points above the minimum SOC threshold 202.

In some examples, during discharge of the energy source 14, responsive to the SOC buffer controller 250 determining that the measured SOC data 215 is between the intermediate SOC 204 and the maximum SOC threshold 206, the SOC buffer controller 250 may be configured to increase the SOC buffer 255. The SOC buffer controller 250 may be configured to increase the SOC buffer 255 each time an updated measured SOC data 215 is obtained, periodically based on a predetermined time period, depending on the SOC decrease rate 225, depending on the SOC difference 235 or combinations thereof. The SOC buffer controller 250 may be configured to increase the SOC buffer 255 by any suitable amount. In some examples, the SOC buffer controller 250 is configured to increase the SOC buffer 255 by an SOC increase value 256. The SOC increase value 256 may be a predetermined fixed value. In some examples, the SOC buffer controller 250 is configured to determine the SOC increase value 256 as a function of the measured SOC data 215. The SOC buffer controller 250 may be configured to determine the SOC increase value 256 based on a predetermined or configurable SOC buffer increase rate.

In order to limit the SOC buffer 255, the SOC buffer controller 250 may be configured to limit the SOC buffer 255 at a predetermined maximum SOC buffer value 258. That is to say, the SOC buffer controller 250 may be configured to increase the SOC buffer 255 as indicated above, until the SOC buffer 255 reaches the maximum SOC buffer value 258, at which point, the SOC buffer 255 is, unless an SOC correction 245 is determined, maintained at the maximum SOC buffer value 258. The SOC increase value 256 and/or the SOC decrease value 252 may be determined based on a difference between the maximum SOC buffer value 258 and the SOC buffer 255. As indicated, if the SOC buffer 255 is equal to the maximum SOC buffer value 258, the SOC increase value 256 may be set to zero. Additionally, or alternatively, as the SOC buffer 255 approaches the maximum SOC buffer value 258, the SOC increase value 256 may de decreased.

In some examples, during discharge of the energy source 14, responsive to the SOC buffer controller 250 determining that the measured SOC data 215 is between the intermediate SOC 204 and the minimum SOC threshold 202, the SOC buffer controller 250 may be configured to decrease the SOC buffer 255. The SOC buffer controller 250 may be configured to decrease the SOC buffer 255 each time an updated measured SOC data 215 is obtained, periodically based on a predetermined time period, depending on the SOC decrease rate 225, depending on the SOC difference 235 or combinations thereof. The SOC buffer controller 250 may be configured to decrease the SOC buffer 255 by any suitable amount. In some examples, the SOC buffer controller 250 is configured to increase the SOC buffer 255 by an SOC decrease value 252. The SOC decrease value 252 may be a predetermined fixed value. In some examples, the SOC buffer controller 250 is configured to determine the SOC decrease value 252 as a function of the measured SOC data 215. The SOC buffer controller 250 may be configured to determine the SOC decrease value 252 based on a predetermined or configurable SOC buffer decrease rate. In some examples, the SOC decrease value 252 is configured such that the SOC buffer 255 is substantially zero when the measured SOC data 215 is at the minimum SOC threshold 202.

In some examples, in order to detect positive shifts, i.e. sudden increases in the measured SOC data 215, the SOC decrease rate determiner 220, may be configured to compare the measured SOC decrease rate 225 to an SOC increase rate threshold 203T2. The SOC increase rate threshold 203T2 may be of the corresponding magnitude as the expected SOC decrease rate threshold 203T or configured independently of the SOC decrease rate threshold 203T. If the SOC decrease rate determiner 220 determines that the measured SOC decrease rate 225 is at or above the SOC increase rate threshold 203T2, the SOC difference determiner 230, the SOC correction determiner 240, the SOC buffer controller 250 and the SOC provider 260 may be configured to operate as previously described but by increasing the SOC buffer 255 by the SOC correction 245 and providing the filtered SOC data 285 as the measured SOC data 215 decreased by the SOC correction 245.

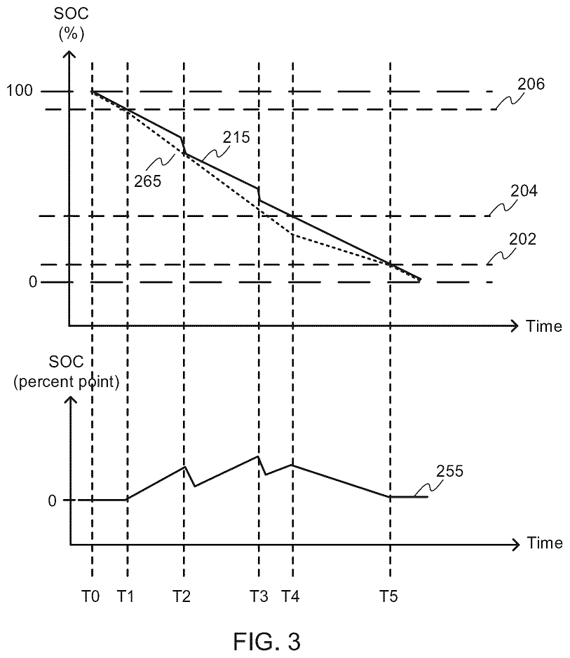

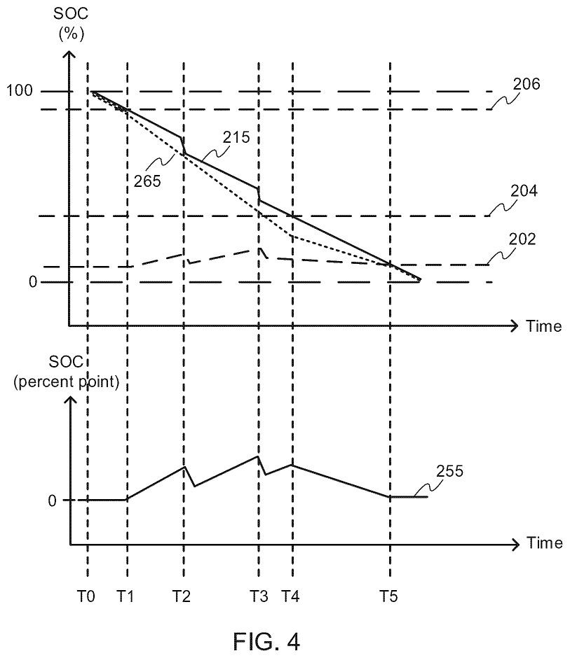

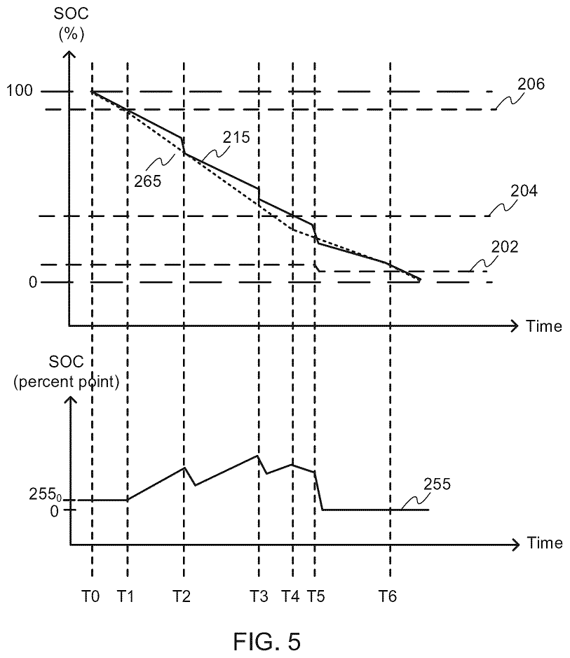

With reference to FIG. 3, FIG. 4 and FIG. 5, some non-limiting examples of how the SOC masker 200 may function will be presented. In both FIG. 3, FIG. 4 and FIG. 5, a top diagram showing SOC in percentage versus time is provided together with a bottom diagram showing the SOC buffer 255 in percentage points of SOC versus time. The time axes are aligned for the top and bottom diagrams. The top diagrams all indicate 100% SOC as their maximum value, this is to be considered to be the level at which the energy source 14 is considered to be fully charged, i.e. not necessarily the physical maximum energy level of the energy source 14. It should be mentioned that the neither the top, nor the bottom diagrams are to scale on their vertical SOC axis. Also, drops/shifts in SOC are exaggerated in order to improve visibility. FIG. 3, FIG. 4 and FIG. 5 are provided to explain different scenarios and implementation examples, and not to accurately represent physical processes in an energy source 14.

In FIG. 3, the SOC buffer 255 is a truly virtual buffer that is provided to mask the measured SOC data 215. At a discharge start time T0, the SOC buffer 255 is zero (empty) and the SOC of the energy source 14 is 100%. This means that the measured SOC data 215 and the filtered SOC data 265 are the same. At the discharge start time T0, discharging of the energy source 14 starts, but since the measured SOC data 215 is above the maximum SOC threshold 206 and above the SOC intermediate threshold 204, the SOC buffer 255 remains empty. At a first point in time T1, the measured SOC data 215 is at the maximum SOC threshold 206. As a consequence, the SOC buffer 255 is increased by the SOC increase value 256 which can be seen in the lower diagram in FIG. 3. As the SOC buffer 255 is increased, the filtered SOC data 265 is decreased correspondingly, which can be seen in the upper diagram of FIG. 3 by the filtered SOC data 265 diverging from the measured SOC data 215. At a second point in time T2, a shift in the measured SOC data 215 occurs. This shift causes the measured SOC decrease rate 225 to be above the expected SOC decrease rate 203 and as a consequence, the SOC buffer 255 is decreased correspondingly to the shift in measured SOC data 215 but no shift in the filtered SOC data 265 occurs due to the SOC buffer 255 compensating for the shift. As the measured SOC data 215 is still below the maximum SOC threshold 206 and above the SOC intermediate threshold 204, the SOC buffer 255 is increased further also after the second point in time T2. At a third point in time T3, another shift in the measured SOC data 215 occurs. As before, this shift causes the measured SOC decrease rate 225 to be above the expected SOC decrease rate 203 and as a consequence, the SOC buffer 255 is decreased correspondingly to the shift in measured SOC data 215 but no shift in the filtered SOC data 265 occurs due to the SOC buffer 255 compensating for the shift. As the measured SOC data 215 is still below the maximum SOC threshold 206 and above the SOC intermediate threshold 204, the SOC buffer 255 is increased further also after the second point in time T3. However, at a fourth point in time T4, the measured SOC data 215 is at the intermediate SOC threshold 204, causing a decrease of the SOC buffer 255 by the SOC decrease value 252. This can be seen by the SOC buffer 255 reducing in the lower diagram of FIG. 3. As the SOC buffer 255 is decreased by the SOC decrease value 252, the filtered SOC data 265 is increased correspondingly which can be seen upper diagram of FIG. 3 by the filtered SOC data 265 converging towards the measured SOC data 215. At a fifth point in time T5, the measured SOC data 215 is at the minimum SOC threshold 202 at which point T5 the propulsion of the vehicle 10 is prohibited. Also, at the fifth point in time T5, the SOC buffer 255 is substantially empty.

In FIG. 4, the SOC buffer 255 may be referred to as a semi-virtual buffer (at least in comparison to the SOC buffer 255 of FIG. 3) that is provided to mask the measured SOC data 215. At a discharge start time T0, the SOC buffer 255 is zero (empty) and the SOC of the energy source 14 is 100%. This means that the measured SOC data 215 and the filtered SOC data 265 are the same. At the discharge start time T0, discharging of the energy source 14 starts, but since the measured SOC data 215 is above the maximum SOC threshold 206 and above the SOC intermediate threshold 204, the SOC buffer 255 remains empty. At a first point in time T1, the measured SOC data 215 is at the maximum SOC threshold 206. As a consequence, the SOC buffer 255 is increased by the SOC increase value 256 which can be seen in the lower diagram in FIG. 4. In FIG. 4, the increase of the SOC buffer 255 is provided by an increase of the minimum SOC threshold 202. This means that the SOC buffer 255 is provided by a difference between a current minimum SOC threshold 202, and the minimum SOC threshold 202 at the first time point T1. As the SOC buffer 255 is increased, the filtered SOC data 265 is decreased correspondingly, which can be seen in the upper diagram of FIG. 4 by the filtered SOC data 265 diverging from the measured SOC data 215. At a second point in time T2, a shift in the measured SOC data 215 occurs. This shift causes the measured SOC decrease rate 225 to be above the expected SOC decrease rate 203 and as a consequence, the SOC buffer 255 is decreased correspondingly to the shift in measured SOC data 215 but no shift in the filtered SOC data 265 occurs due to the SOC buffer 255 compensating for the shift. As the SOC buffer 255 decreases, so does the minimum SOC threshold 202. As the measured SOC data 215 is still below the maximum SOC threshold 206 and above the SOC intermediate threshold 204, the SOC buffer 255 and consequently the minimum SOC threshold 202 is increased further also after the second point in time T2. At a third point in time T3, another shift in the measured SOC data 215 occurs. As before, this shift causes the measured SOC decrease rate 225 to be above the expected SOC decrease rate 203 and as a consequence, the SOC buffer 255 and thereby the minimum SOC threshold 202 is decreased correspondingly to the shift in measured SOC data 215 but no shift in the filtered SOC data 265 occurs due to the SOC buffer 255 compensating for the shift. As the measured SOC data 215 is still below the maximum SOC threshold 206 and above the SOC intermediate threshold 204, the SOC buffer 255 is increased further also after the second point in time T3. However, at a fourth point in time T4, the measured SOC data 215 is at the intermediate SOC threshold 204, and decreasing of the SOC buffer 255 by the SOC decrease value 252. This can be seen by the SOC buffer 255 reducing in the lower diagram of FIG. 4 and the minimum SOC threshold 202 returning to the level of the minimum SOC threshold 202 at the start time T0. As the SOC buffer 255 is decreased by the SOC decrease value 252, the filtered SOC data 265 is increased correspondingly which can be seen upper diagram of FIG. 4 by the filtered SOC data 265 converging towards the measured SOC data 215. At a fifth point in time T5, the measured SOC data 215 is at the minimum SOC threshold 202 (which is at the corresponding level as the minimum SOC threshold 202 at the start time T0) at which point T5 the propulsion of the vehicle 10 is prohibited. Also, at the fifth point in time T5, the SOC buffer 255 is substantially empty.

In FIG. 5, the SOC buffer 255 may be described as a combination of the SOC buffer 255 exemplified in FIG. 3 and a variant of the SOC buffer 255 exemplified in FIG. 4. In FIG. 5, at a discharge start time T0, the SOC buffer 255 is at an initial SOC buffer level 2550 and the SOC of the energy source 14 is 100%. However, even though the initial SOC buffer level 2550 is greater than zero, the measured SOC data 215 and the filtered SOC data 265 are the same at the discharge start time T0. At the discharge start time T0, discharging of the energy source 14 starts, but since the measured SOC data 215 is above the maximum SOC threshold 206 and above the SOC intermediate threshold 204, the SOC buffer 255 remains empty. At a first point in time T1, the measured SOC data 215 is at the maximum SOC threshold 206. As a consequence, the SOC buffer 255 is increased by the SOC increase value 256 which can be seen in the lower diagram in FIG. 5. As the SOC buffer 255 is increased, the filtered SOC data 265 is decreased correspondingly, which can be seen in the upper diagram of FIG. 3 by the filtered SOC data 265 diverging from the measured SOC data 215. At a second point in time T2, a shift in the measured SOC data 215 occurs. This shift causes the measured SOC decrease rate 225 to be above the expected SOC decrease rate 203 and as a consequence, the SOC buffer 255 is decreased correspondingly to the shift in measured SOC data 215 but no shift in the filtered SOC data 265 occurs due to the SOC buffer 255 compensating for the shift. As the measured SOC data 215 is still below the maximum SOC threshold 206 and above the SOC intermediate threshold 204, the SOC buffer 255 is increased further also after the second point in time T2. At a third point in time T3, another shift in the measured SOC data 215 occurs. As before, this shift causes the measured SOC decrease rate 225 to be above the expected SOC decrease rate 203 and as a consequence, the SOC buffer 255 is decreased correspondingly to the shift in measured SOC data 215 but no shift in the filtered SOC data 265 occurs due to the SOC buffer 255 compensating for the shift. As the measured SOC data 215 is still below the maximum SOC threshold 206 and above the SOC intermediate threshold 204, the SOC buffer 255 is increased further also after the second point in time T3. However, at a fourth point in time T4, the measured SOC data 215 is at the intermediate SOC threshold 204, and decreasing of the SOC buffer 255 by the SOC decrease value 252. This can be seen by the SOC buffer 255 reducing in the lower diagram of FIG. 5. As the SOC buffer 255 is decreased by the SOC decrease value 252, the filtered SOC data 265 is increased correspondingly which can be seen upper diagram of FIG. 5 by the filtered SOC data 265 converging towards the measured SOC data 215. At a fifth point in time T5, a third shift in the measured SOC data 215 occurs. As before, this shift causes the measured SOC decrease rate 225 to be above the expected SOC decrease rate 203. However, the shift is greater than the remainder of what has been accumulated by the SOC buffer 255 from the first point in time T1. In some examples, this would cause the SOC buffer 255 to be emptied leaving a shift, admittedly a reduced shift from that of the measured SOC data 215, in the filtered SOC data 265. However, as the SOC buffer 255 had was configured at the initial SOC buffer level 2550 at the start time T0, the SOC buffer 255 may be further reduced. The initial SOC buffer level 2550 is provided by the minimum SOC threshold 202, and the shift in measured SOC data 215 may be compensated by reducing the minimum SOC threshold 202, see upper diagram of the FIG. 5. As a result, the measured SOC data 215 is below the filtered SOC data 265 after the fifth point in time T5. Discharge of the energy source proceeds and the filtered SOC data 265 is decreased such that the measured SOC data 215 and the filtered SOC data 265 are equal before, or at, a sixth point in time T6 at which point the measured SOC data 215 is at the minimum SOC threshold 202 and propulsion of the vehicle 10 is prohibited.

The examples presented with reference to FIG. 3, FIG. 4 and FIG. 5 are, as mentioned, non-limiting examples provided to explain some, but not all, features of the SOC masker 200 introduced with reference to FIG. 2. For instance, the SOC buffer 255 reaching the SOC maximum buffer value 258 is not explicitly shown, but is well within the scope of all examples presented herein. Further, in FIG. 3, FIG. 4 and FIG. 5, the shifts in measured SOC data 215 are substantially removed in the filtered SOC data 265. However, as mentioned, in some examples, the SOC correction 240 may not necessarily equal to the SOC difference 235 and shifts also in the filtered SOC data 265 may be permitted.

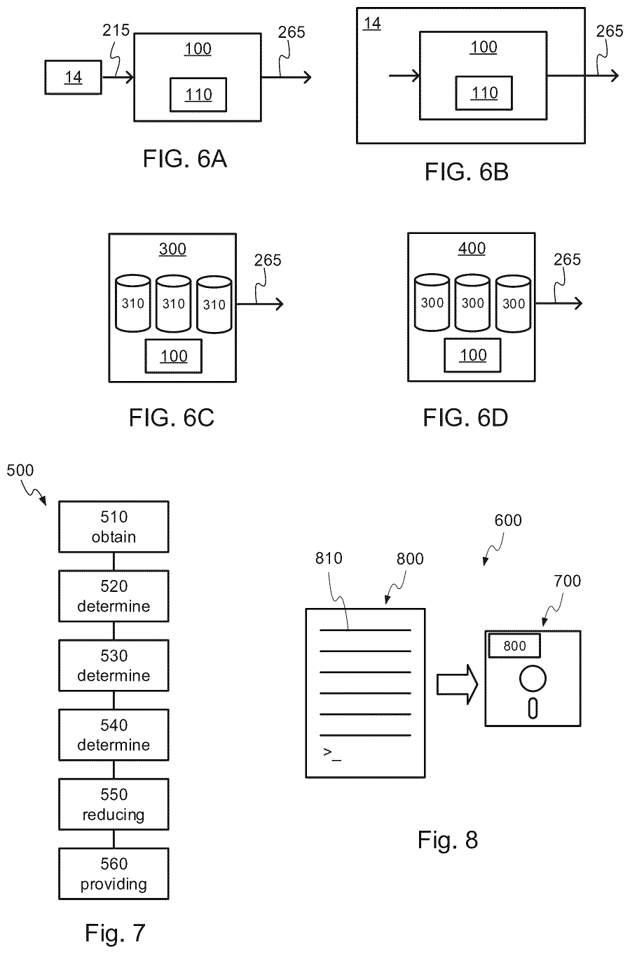

As indicated, the computer system 100 may be configured to provide, or cause, the functionality of the SOC masker 200. To this end, as indicated in FIG. 6A, the computer system 100 may be operatively connected to the energy source 14 and configured to obtain measured SOC data 215 from the energy source 14 and provide filtered SOC data 265 for further processing.

In one specific example, the computer system 100 of e.g. FIG. 6A comprises processing circuitry 110 configured to obtain measured SOC data 215 of an energy source 14 of a vehicle 10. The processing circuitry 110 is further configured to determine that a measured SOC decrease rate 225 is above an expected SOC decrease rate 203 by a predetermined SOC decrease rate threshold 203T and to determine an SOC difference 235 based on the measured SOC data 215 and the expected SOC decrease rate 203. The processing circuitry 110 is further configured to determine an SOC correction 245 based on the SOC difference 235, reduce an

SOC buffer 255 of the energy source 14 by the SOC correction 245, and provide filtered SOC data 265 of the energy source 14 by increasing the measured SOC data 215 by the SOC correction 245.

In some examples, see FIG. 6B, the computer system 100, or at least processing circuitry 110 forming part of the computer system 100, may form part of the energy source 14. The computer system 100 may be configured to obtain measured SOC data 215 of the energy source 14 and provide filtered SOC data 265 for further processing.

The computer system 100 may be part of a battery pack 300, see FIG. 6C. The battery pack 300 may comprise one or more battery cells 310. The computer system 100 may be configured to obtain measured SOC data 215 from at least one of the one or more battery cells 310 and provide filtered SOC data 265 for further processing.

In some examples, see FIG. 6D, the computer system 100 may form part of an energy management system 400. The energy management system 400 comprises one or more battery packs 300, e.g. the battery pack 300 of FIG. 6C. The computer system 100 may be configured to obtain measured SOC data 215 from at least one of the one or more battery packs 300 and provide filtered SOC data 265 for further processing.

As indicated in the previous, the functionality of the SOC masker 200 may be provided at substantially any or all levels of an energy supply of a vehicle 10. One or more battery cells 310 may comprise processing circuitry 110 configured to perform the functionality of the SOC masker 200 and provide filtered SOC data 265 for further processing. The filtered SOC data 265 from the battery cell 310 may be obtained as measured SOC data 215 by processing circuitry 110 of a battery pack 300 configured to perform the functionality of the SOC masker 200 and provide filtered SOC data 265 for further processing. The filtered SOC data 265 from the battery pack 300 may be obtained as measured SOC data 215 by processing circuitry 110 of a battery management system 400 configured to perform the functionality of the SOC masker 200 and provide filtered SOC data 265 for further processing.

With reference to FIG. 7, a method 500 according to one example of the present disclosure will be presented. The method 500 may be a partly, or wholly, computer implemented method 500. In some examples, the computer system 100, or rather processing circuitry 110 of the computer system 100 introduced with reference to FIG. 1, may be configured to perform, or cause performance of, any or all features of the method 500. The method 500 may be described as a method 500 for SOC masking.

The method 500 comprises obtaining 510 measured state of charge, SOC, data 215 of an energy source 14 of a vehicle 10. The obtaining 510 may be provided as outlined e.g. in reference to the SOC obtainer 210 introduced with reference to FIG. 2. The method 500 further comprises determining 520 that a measured SOC decrease rate 225 is above an expected SOC decrease rate 203 by a predetermined SOC decrease rate threshold 203T. This determining 530 may be provided as outlined e.g. in reference to the SOC decrease rate determiner 220 introduced with reference to FIG. 2. The method 500 further comprises determining 530 an SOC difference 235 based on the measured SOC data 215 and the expected SOC decrease rate 203. This determining 530 may be provided as outlined e.g. in reference to the SOC difference determiner 230 introduced with reference to FIG. 2. The method 500 further comprises determining 540 an SOC correction 245 based on the SOC difference 235. This determining 540 may be provided as outlined with reference to the SOC correction determiner 240 introduced with reference to FIG. 2. The method 500 further comprises reducing 550 an SOC buffer 255 of the energy source 14 by the SOC correction 245. Reducing the SOC buffer 255 may be provided as outlined e.g. in reference to the SOC buffer controller 250 introduced with reference to FIG. 2. The method 500 further comprises providing 560 filtered SOC data 265 of the energy source 14 by increasing the measured SOC data 215 by the SOC correction 245. The providing 560 may be provided as outlined e.g. in reference to the SOC provider 560 introduced with reference to FIG. 2.

The method 500 of FIG. 7, may be modified, expanded or otherwise altered to comprise any or all features, examples or functions presented herein, e.g. in reference to the SOC masker introduced in reference to FIG. 2.

In FIG. 8 a computer program product 600 is shown. The computer program product 600 comprises a computer program 800 and a non-transitory computer readable medium 700. The computer program 800 may be stored on the computer readable medium 700. The computer readable medium 700 is, in FIG. 8, exemplified as a vintage 5,25″ floppy disc, but may be embodied as any suitable non-transitory computer readable medium such as, but not limited to, hard disk drives (HDDs), solid-state drives (SSDs), optical discs (e.g., CD-ROM, DVD-ROM, CD-RW, DVD-RW), USB flash drives, magnetic tapes, memory cards, Read-Only Memories (ROM), network-attached storage (NAS), cloud storage etc.

The computer program 800 comprises instruction 810 e.g. program instruction, software code, that, when executed by processing circuitry cause the processing circuitry to perform the method 500 introduced with reference to FIG. 7.

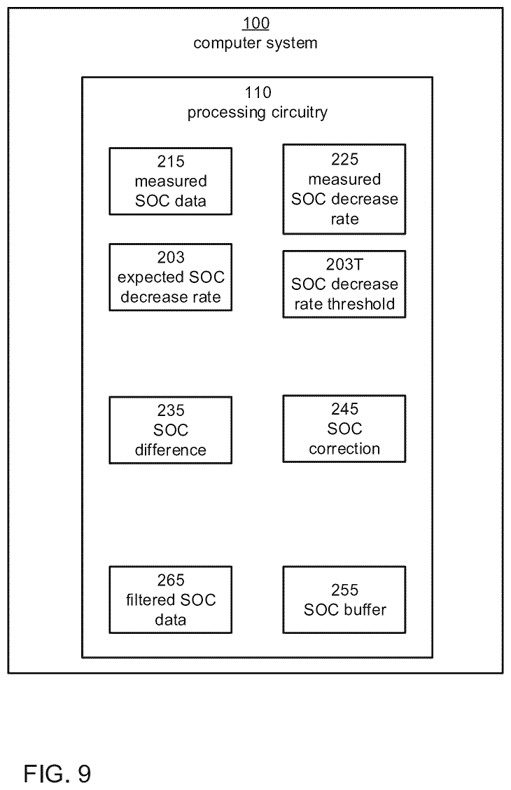

With reference to FIG. 9, a computer system 100 is shown. The computer system 100 comprises processing circuitry 110 configured to obtain measured state of charge, SOC, data 215 of an energy source 14 of a vehicle 10, and determine that a measured SOC decrease rate 225 is above an expected SOC decrease rate 203 by a predetermined SOC decrease rate threshold 203T. The processing circuitry 110 is further configured to determine an SOC difference 235 based on the measured SOC data 215 and the expected SOC decrease rate 203, to determine an SOC correction 245 based on the SOC difference 235, to reduce an SOC buffer 255 of the energy source 14 by the SOC correction 245; and to provide filtered SOC data 265 of the energy source 14 by increasing the measured SOC data 215 by the SOC correction 245.

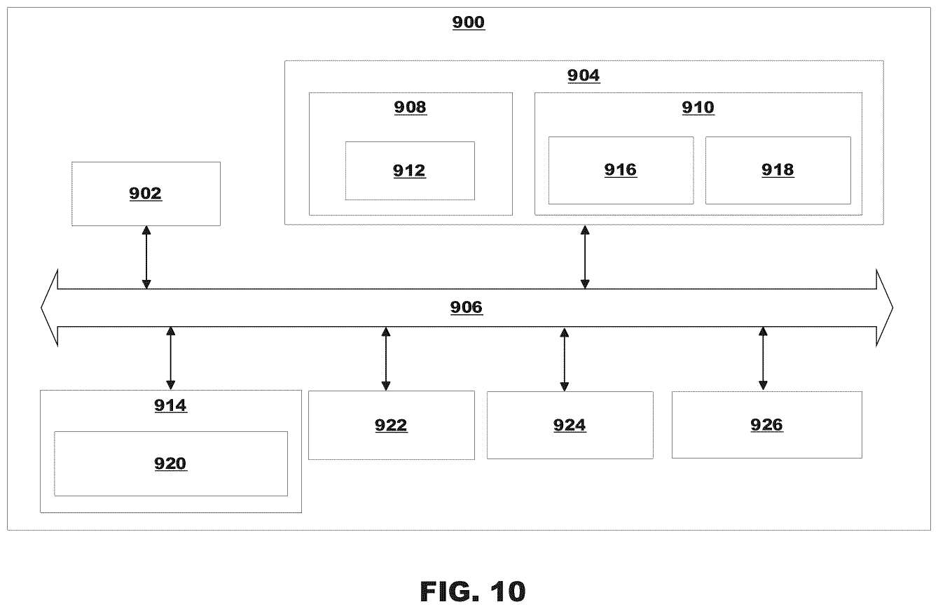

FIG. 10 is a schematic diagram of a computer system 900 for implementing examples disclosed herein. The computer system 900 may be the computer system 100 introduced with reference to FIG. 1. The computer system 900 is adapted to execute instructions from a computer-readable medium to perform these and/or any of the functions or processing described herein. The computer system 900 may be connected (e.g., networked) to other machines in a LAN, an intranet, an extranet, or the Internet. While only a single device is illustrated, the computer system 900 may include any collection of devices that individually or jointly execute a set (or multiple sets) of instructions to perform any one or more of the methodologies discussed herein. Accordingly, any reference in the disclosure and/or claims to a computer system, computing system, computer device, computing device, control system, control unit, electronic control unit (ECU), processor device, processing circuitry, etc., includes reference to one or more such devices to individually or jointly execute a set (or multiple sets) of instructions to perform any one or more of the methodologies discussed herein. For example, control system may include a single control unit or a plurality of control units connected or otherwise communicatively coupled to each other, such that any performed function may be distributed between the control units as desired. Further, such devices may communicate with each other or other devices by various system architectures, such as directly or via a Controller Area Network (CAN) bus, etc.

The computer system 900 may comprise at least one computing device or electronic device capable of including firmware, hardware, and/or executing software instructions to implement the functionality described herein. The computer system 900 may include processing circuitry 902 (e.g., processing circuitry including one or more processor devices or control units), a memory 904, and a system bus 906. The processing circuitry 902 may comprise the processing circuitry 110 of the computer system 100 introduced with reference to FIG. 1. The computer system 900 may include at least one computing device having the processing circuitry 902. The system bus 906 provides an interface for system components including, but not limited to, the memory 904 and the processing circuitry 902. The processing circuitry 902 may include any number of hardware components for conducting data or signal processing or for executing computer code stored in memory 904. The processing circuitry 902 may, for example, include a general-purpose processor, an application specific processor, a Digital Signal Processor (DSP), an Application Specific Integrated Circuit (ASIC), a Field Programmable Gate Array (FPGA), a circuit containing processing components, a group of distributed processing components, a group of distributed computers configured for processing, or other programmable logic device, discrete gate or transistor logic, discrete hardware components, or any combination thereof designed to perform the functions described herein. The processing circuitry 902 may further include computer executable code that controls operation of the programmable device.

The system bus 906 may be any of several types of bus structures that may further interconnect to a memory bus (with or without a memory controller), a peripheral bus, and/or a local bus using any of a variety of bus architectures. The memory 904 may be one or more devices for storing data and/or computer code for completing or facilitating methods described herein. The memory 904 may include database components, object code components, script components, or other types of information structure for supporting the various activities herein. Any distributed or local memory device may be utilized with the systems and methods of this description. The memory 904 may be communicably connected to the processing circuitry 902 (e.g., via a circuit or any other wired, wireless, or network connection) and may include computer code for executing one or more processes described herein. The memory 904 may include non-volatile memory 908 (e.g., read-only memory (ROM), erasable programmable read-only memory (EPROM), electrically erasable programmable read-only memory (EEPROM), etc.), and volatile memory 910 (e.g., random-access memory (RAM)), or any other medium which can be used to carry or store desired program code in the form of machine-executable instructions or data structures and which can be accessed by a computer or other machine with processing circuitry 902. A basic input/output system (BIOS) 912 may be stored in the non-volatile memory 908 and can include the basic routines that help to transfer information between elements within the computer system 900.

The computer system 900 may further include or be coupled to a non-transitory computer-readable storage medium such as the storage device 914, which may comprise, for example, an internal or external hard disk drive (HDD) (e.g., enhanced integrated drive electronics (EIDE) or serial advanced technology attachment (SATA)), HDD (e.g., EIDE or SATA) for storage, flash memory, or the like. The storage device 914 and other drives associated with computer-readable media and computer-usable media may provide non-volatile storage of data, data structures, computer-executable instructions, and the like.

Computer-code which is hard or soft coded may be provided in the form of one or more modules. The module(s) can be implemented as software and/or hard-coded in circuitry to implement the functionality described herein in whole or in part. The modules may be stored in the storage device 914 and/or in the volatile memory 910, which may include an operating system 916 and/or one or more program modules 918. All or a portion of the examples disclosed herein may be implemented as a computer program 920 stored on a transitory or non-transitory computer-usable or computer-readable storage medium (e.g., single medium or multiple media), such as the storage device 914, which includes complex programming instructions (e.g., complex computer-readable program code) to cause the processing circuitry 902 to carry out actions described herein. Thus, the computer-readable program code of the computer program 920 can comprise software instructions for implementing the functionality of the examples described herein when executed by the processing circuitry 902. In some examples, the storage device 914 may be a computer program product (e.g., readable storage medium) storing the computer program 920 thereon, where at least a portion of a computer program 920 may be loadable (e.g., into a processor) for implementing the functionality of the examples described herein when executed by the processing circuitry 902. The processing circuitry 902 may serve as a controller or control system for the computer system 900 that is to implement the functionality described herein.

The computer system 900 may include an input device interface 922 configured to receive input and selections to be communicated to the computer system 900 when executing instructions, such as from a keyboard, mouse, touch-sensitive surface, etc. Such input devices may be connected to the processing circuitry 902 through the input device interface 922 coupled to the system bus 906 but can be connected through other interfaces, such as a parallel port, an Institute of Electrical and Electronic Engineers (IEEE) 1394 serial port, a Universal Serial Bus (USB) port, an IR interface, and the like. The computer system 900 may include an output device interface 924 configured to forward output, such as to a display, a video display unit (e.g., a liquid crystal display (LCD) or a cathode ray tube (CRT)). The computer system 900 may include a communications interface 926 suitable for communicating with a network as appropriate or desired.

The operational actions described in any of the exemplary aspects herein are described to provide examples and discussion. The actions may be performed by hardware components, may be embodied in machine-executable instructions to cause a processor to perform the actions, or may be performed by a combination of hardware and software. Although a specific order of method actions may be shown or described, the order of the actions may differ. In addition, two or more actions may be performed concurrently or with partial concurrence.

In the following, a number of specific examples of the present disclosure will be presented. The scope of the invention is defined by the appended claims.
Example 1. A computer system 100 comprising processing circuitry 110 configured to: obtain measured state of charge, SOC, data 215 of an energy source 14 of a vehicle 10, determine that a measured SOC decrease rate 225 is above an expected SOC decrease rate 203 by a predetermined SOC decrease rate threshold 203T; determine an SOC difference 235 based on the measured SOC data 215 and the expected SOC decrease rate 203; determine an SOC correction 245 based on the SOC difference 235; reduce an SOC buffer 255 of the energy source 14 by the SOC correction 245; and provide filtered SOC data 265 of the energy source 14 by increasing the measured SOC data 215 by the SOC correction 245.
Example 2. The computer system 100 of example 1, wherein the processing circuitry is further configured to: determine the expected SOC decrease rate 203 based on energy drained from the energy source 14.
Example 3. The computer system 100 of example 1 or 2, wherein the processing circuitry 110 is further configured to: determine that the measured SOC data 215 is below a predetermined maximum SOC threshold 206 and above an intermediate SOC threshold 204; increase the SOC buffer 255 by an SOC increase value 256; and provide filtered SOC data 265 of the energy source 14 by decreasing the measured SOC data 215 by the SOC increase value 256.
Example 4. The computer system 100 of example 3, wherein the processing circuitry 110 is further configured to: determine the SOC increase value 256 as a function of the measured SOC data 215.
Example 5. The computer system 100 of example 3, wherein the processing circuitry 110 is further configured to: determine the SOC increase value 256 at a predetermined fixed value.
Example 6. The computer system 100 of any one of examples 1 to 5, wherein the processing circuitry 110 is further configured to: determine that the measured SOC data 215 is below the intermediate SOC threshold 204 and above a minimum SOC threshold 202; decrease the SOC buffer 255 by an SOC decrease value 252; and provide filtered SOC data 265 of the energy source 14 by increasing the measured SOC data 215 by the SOC decrease value 252.
Example 7. The computer system 100 of example 6, wherein the processing circuitry 110 is further configured to: determine the SOC decrease value 252 as a function of the measured SOC data 215.
Example 8. The computer system 100 of example 7, wherein the processing circuitry 110 is further configured to: determine the SOC decrease value 252 at a predetermined fixed value.
Example 9. The computer system 100 of any one of examples 1 to 8, wherein the processing circuitry 110 is further configured to: limit the SOC buffer 255 at a predetermined maximum SOC buffer value 258.
Example 10. The computer system 100 of any one of examples 1 to 9, wherein the processing circuitry 110 is further configured to: prevent propulsion of the vehicle 10 responsive to the measured SOC data 215 being below a minimum SOC threshold 202.
Example 11. The computer system 100 of example 6 and 10, wherein the processing circuitry 110 is further configured to: determine the SOC decrease value 252 such that the SOC buffer 255 is substantially zero when the measured SOC data 215 is at the minimum SOC threshold 202.
Example 12. The computer system 100 of example 11, wherein the processing circuitry 110 is further configured to: determine that the SOC difference 235 is greater than the SOC buffer 255; and reduce the minimum SOC threshold 202 by the by the SOC correction 245.
Example 13. The computer system 100 of example any one of examples 1 to 9, wherein SOC buffer 255 is equal to a minimum SOC threshold 202, and the processing circuitry 110 is further configured to: prevent propulsion of the vehicle 10 responsive to the measured SOC data 215 being below the minimum SOC threshold 202.
Example 14. The computer system 100 of any one of examples 1 to 13, wherein the processing circuitry 110 is further configured to: determine that an SOC decrease rate 225 is above the expected SOC decrease rate 203 by comparing measured SOC data 215 to previous measured SOC data 215.
Example 15. The computer system 100 of any one of example 1 to 14, wherein the processing circuitry 110 is further configured to: determine that an SOC decrease rate 225 is above the expected SOC decrease rate 203 by obtaining an SOC data calibration event indicator 14c from the energy source 14.
Example 16. The computer system 100 of example 1, wherein the processing circuitry 110 is further configured to: determine the processing circuitry 110 is further configured to: determine that an SOC decrease rate 225 is above the expected SOC decrease rate 203 by obtaining an SOC data calibration event indicator 14c from the energy source 14; expected SOC decrease rate 203 based on energy drained from the energy source 14; determine that the measured SOC data 215 is below a predetermined maximum SOC threshold 206 and above an intermediate SOC threshold 204; increase the SOC buffer 255 by an SOC increase value 256; and provide filtered SOC data 265 of the energy source 14 by decreasing the measured SOC data 215 by the SOC increase value 256; determine the SOC increase value 256 as a function of the measured SOC data 215; determine the SOC increase value 256 at a predetermined fixed value; determine that the measured SOC data 215 is below the intermediate SOC threshold 204 and above a minimum SOC threshold 204; decrease the SOC buffer 255 by an SOC decrease value 252; and provide filtered SOC data 265 of the energy source 14 by increasing the measured SOC data 215 by the SOC decrease value 252; determine the SOC decrease value 252 as a function of the measured SOC data 215; determine the SOC decrease value 252 at a predetermined fixed value; limit the SOC buffer 255 at a predetermined maximum SOC buffer value 258; prevent propulsion of the vehicle 10 responsive to the measured SOC data 215 being below a minimum SOC threshold 202; determine the SOC decrease value 252 such that the SOC buffer 255 is substantially zero when the measured SOC data 215 is at the minimum SOC threshold 202; determine that the SOC difference 235 is greater than the SOC buffer 255; and reduce the minimum SOC threshold 202 by the by the SOC correction 245; determine that an SOC decrease rate 225 is above the expected SOC decrease rate 203 by comparing measured SOC data 215 to previous measured SOC data 215; and determine that an SOC decrease rate 225 is above the expected SOC decrease rate 203 by obtaining an SOC data calibration event indicator 14c from the energy source 14
Example 17. The computer system 100 of example 1, wherein the processing circuitry 110 is further configured to: determine that an SOC decrease rate 225 is above the expected SOC decrease rate 203 by obtaining an SOC data calibration event indicator 14c from the energy source 14; determine the expected SOC decrease rate 203 based on energy drained from the energy source 14; determine that the measured SOC data 215 is below a predetermined maximum SOC threshold 206 and above an intermediate SOC threshold 204; increase the SOC buffer 255 by an SOC increase value 256; and provide filtered SOC data 265 of the energy source 14 by decreasing the measured SOC data 215 by the SOC increase value 256; determine the SOC increase value 256 as a function of the measured SOC data 215; determine the SOC increase value 256 at a predetermined fixed value; determine that the measured SOC data 215 is below the intermediate SOC threshold 204 and above a minimum SOC threshold 202; decrease the SOC buffer 255 by an SOC decrease value 252; and provide filtered SOC data 265 of the energy source 14 by increasing the measured SOC data 215 by the SOC decrease value 252; determine the SOC decrease value 252 as a function of the measured SOC data 215; determine the SOC decrease value 252 at a predetermined fixed value; limit the SOC buffer 255 at a predetermined maximum SOC buffer value 258; wherein SOC buffer 255 is equal to a minimum SOC threshold 202, and the processing circuitry 110 is further configured to: prevent propulsion of the vehicle 10 responsive to the measured SOC data 215 being below the minimum SOC threshold 202; determine that an SOC decrease rate 225 is above the expected SOC decrease rate 203 by comparing measured SOC data 215 to previous measured SOC data 215; and determine that an SOC decrease rate 225 is above the expected SOC decrease rate 203 by obtaining an SOC data calibration event indicator 14c from the energy source 14.
Example 18. A battery pack 300, comprising one or more battery cells 310 and the computer system 100 of any one of examples 1 to 17 configured to obtain measured SOC data 215 of at least one of the one or more battery cells 310.
Example 19. An energy management system 400, comprising one or more battery packs 300 and the computer system 100 of any one of examples 1 to 16 configured to obtain measured SOC data 215 of at least one of the one or more battery packs 300.
Example 20. A vehicle 10 comprising one or more energy sources 14 and the computer system 100 of any one of examples 1 to 17 configured to obtain measured SOC data 215 of at least one of the one or more energy sources 14.
Example 21. A computer implemented method 500 comprising: obtaining 510, by processing circuitry 110 of a computer system 100, measured state of charge, SOC, data 215 of an energy source 14 of a vehicle 10, determining 520, by processing circuitry 110 of the computer system 100, that a measured SOC decrease rate 225 is above an expected SOC decrease rate 203 by a predetermined SOC decrease rate threshold 203T; determining 530, by processing circuitry 110 of the computer system 100, an SOC difference 235 based on the measured SOC data 215 and the expected SOC decrease rate 203; determining 540, by processing circuitry 110 of the computer system 100, an SOC correction 245 based on the SOC difference 235; reducing 550, by processing circuitry 110 of the computer system 100, an SOC buffer 255 of the energy source 14 by the SOC correction 245; and providing 560, by processing circuitry 110 of the computer system 100, filtered SOC data 265 of the energy source 14 by increasing the measured SOC data 215 by the SOC correction 245.
Example 22. A computer program product 600 comprising program code 810 for performing, when executed by processing circuitry 110, the computer implemented method 500 of example 21.
Example 23. A non-transitory computer-readable storage medium 700 comprising instructions 810, which when executed by processing circuitry 110, cause the processing circuitry 110 to perform the computer implemented method 500 of example 21.

The terminology used herein is for the purpose of describing particular aspects only and is not intended to be limiting of the disclosure. As used herein, the singular forms “a,” “an,” and “the” are intended to include the plural forms as well, unless the context clearly indicates otherwise. As used herein, the term “and/or” includes any and all combinations of one or more of the associated listed items. It will be further understood that the terms “comprises,” “comprising,” “includes,” and/or “including” when used herein specify the presence of stated features, integers, actions, steps, operations, elements, and/or components, but do not preclude the presence or addition of one or more other features, integers, actions, steps, operations, elements, components, and/or groups thereof.

It will be understood that, although the terms first, second, etc., may be used herein to describe various elements, these elements should not be limited by these terms. These terms are only used to distinguish one element from another. For example, a first element could be termed a second element, and, similarly, a second element could be termed a first element without departing from the scope of the present disclosure.

Relative terms such as “below” or “above” or “upper” or “lower” or “horizontal” or “vertical” may be used herein to describe a relationship of one element to another element as illustrated in the Figures. It will be understood that these terms and those discussed above are intended to encompass different orientations of the device in addition to the orientation depicted in the Figures. It will be understood that when an element is referred to as being “connected” or “coupled” to another element, it can be directly connected or coupled to the other element, or intervening elements may be present. In contrast, when an element is referred to as being “directly connected” or “directly coupled” to another element, there are no intervening elements present.

Unless otherwise defined, all terms (including technical and scientific terms) used herein have the same meaning as commonly understood by one of ordinary skill in the art to which this disclosure belongs. It will be further understood that terms used herein should be interpreted as having a meaning consistent with their meaning in the context of this specification and the relevant art and will not be interpreted in an idealized or overly formal sense unless expressly so defined herein.

It is to be understood that the present disclosure is not limited to the aspects described above and illustrated in the drawings; rather, the skilled person will recognize that many changes and modifications may be made within the scope of the present disclosure and appended claims. In the drawings and specification, there have been disclosed aspects for purposes of illustration only and not for purposes of limitation, the scope of the disclosure being set forth in the following claims.

What is claimed is:

1. A computer system comprising processing circuitry configured to:
obtain measured state of charge (SOC) data of an energy source of a vehicle,
determine that a measured SOC decrease rate is above an expected SOC decrease rate by a predetermined SOC decrease rate threshold;
determine an SOC difference based on the measured SOC data and the expected SOC decrease rate;
determine an SOC correction based on the SOC difference;
reduce an SOC buffer of the energy source by the SOC correction; and
provide filtered SOC data of the energy source by increasing the measured SOC data by the SOC correction.

2. The computer system of claim 1, wherein the processing circuitry is further configured to:
determine the expected SOC decrease rate based on energy drained from the energy source.

3. The computer system of claim 1, wherein the processing circuitry is further configured to:
determine that the measured SOC data is below a predetermined maximum SOC threshold and above an intermediate SOC threshold;
increase the SOC buffer by an SOC increase value; and
provide filtered SOC data of the energy source by decreasing the measured SOC data by the SOC increase value.

4. The computer system of claim 3, wherein the processing circuitry is further configured to:
determine the SOC increase value as a function of the measured SOC data.

5. The computer system of claim 3, wherein the processing circuitry is further configured to:
determine the SOC increase value at a predetermined fixed value.

6. The computer system of claim 1, wherein the processing circuitry is further configured to:
determine that the measured SOC data is below the intermediate SOC threshold and above a minimum SOC threshold;
decrease the SOC buffer by an SOC decrease value; and
provide filtered SOC data of the energy source by increasing the measured SOC data by the SOC decrease value.

7. The computer system of claim 6, wherein the processing circuitry is further configured to:
determine the SOC decrease value as a function of the measured SOC data.

8. The computer system of claim 7, wherein the processing circuitry is further configured to:
determine the SOC decrease value at a predetermined fixed value.

9. The computer system of claim 1, wherein the processing circuitry is further configured to:
limit the SOC buffer at a predetermined maximum SOC buffer value.

10. The computer system of claim 6, wherein the processing circuitry is further configured to:
determine the SOC decrease value such that the SOC buffer is substantially zero when the measured SOC data is at the minimum SOC threshold.

11. The computer system of claim 1, wherein the processing circuitry is further configured to:
determine that the SOC difference is greater than the SOC buffer;
reduce a minimum SOC threshold by the by the SOC correction; and
prevent propulsion of the vehicle responsive to the measured SOC data being below the minimum SOC threshold.

12. The computer system of claim 1, wherein the SOC buffer is equal to a minimum SOC threshold, and the processing circuitry is further configured to:
prevent propulsion of the vehicle responsive to the measured SOC data being below the minimum SOC threshold.

13. The computer system of claim 1, wherein the processing circuitry is further configured to:
determine that an SOC decrease rate is above the expected SOC decrease rate by comparing measured SOC data to previous measured SOC data.

14. The computer system of claim 1, wherein the processing circuitry is further configured to:
determine the expected SOC decrease rate based on energy drained from the energy source;
determine that the measured SOC data is below a predetermined maximum SOC threshold and above an intermediate SOC threshold, increase the SOC buffer by an SOC increase value, and provide filtered SOC data of the energy source by decreasing the measured SOC data by the SOC increase value;
determine that the measured SOC data is below the intermediate SOC threshold and above a minimum SOC threshold, decrease the SOC buffer by an SOC decrease value, and provide filtered SOC data of the energy source by increasing the measured SOC data by the SOC decrease value;
determine the SOC decrease value such that the SOC buffer is substantially zero when the measured SOC data is at the minimum SOC threshold;
determine that the SOC difference is greater than the SOC buffer, reduce a minimum SOC threshold by the SOC correction, and prevent propulsion of the vehicle responsive to the measured SOC data being below the minimum SOC threshold;
determine that an SOC decrease rate is above the expected SOC decrease rate by comparing measured SOC data to previous measured SOC data; and
determine that an SOC decrease rate is above the expected SOC decrease rate by obtaining an SOC data calibration event indicator from the energy source.

15. A battery pack, comprising one or more battery cells and the computer system of claim 1 configured to obtain measured SOC data of at least one of the one or more battery cells.

16. An energy management system, comprising one or more battery packs and the computer system of claim 1 configured to obtain measured SOC data of at least one of the one or more battery packs.

17. A vehicle comprising one or more energy sources and the computer system of claim 1 configured to obtain measured SOC data of at least one of the one or more energy sources.

18. A computer implemented method comprising:
obtaining, by processing circuitry of a computer system, measured state of charge (SOC) data of an energy source of a vehicle;
determining, by processing circuitry of the computer system, that a measured SOC decrease rate is above an expected SOC decrease rate by a predetermined SOC decrease rate threshold;
determining, by processing circuitry of the computer system, an SOC difference based on the measured SOC data and the expected SOC decrease rate;
determining, by processing circuitry of the computer system, an SOC correction based on the SOC difference;
reducing, by processing circuitry of the computer system, an SOC buffer of the energy source by the SOC correction; and
providing, by processing circuitry of the computer system, filtered SOC data of the energy source by increasing the measured SOC data by the SOC correction.

19. A computer program product comprising program code for performing, when executed by processing circuitry, the computer implemented method of claim 18.

20. A non-transitory computer-readable storage medium comprising instructions, which when executed by processing circuitry, cause the processing circuitry to perform the computer implemented method of claim 18.
